(19) United States
(12) Patent Application Publication
(10) Pub. No.: US 2025/0224866 A1
(43) Pub. Date: Jul. 10, 2025

(54) METHOD FOR MANAGING FLASH MEMORY AND FLASH MEMORY DEVICE

(71) Applicant: DapuStor Corporation, Shenzhen (CN)

(72) Inventors: Xiang CHEN, Shenzhen (CN); Hongbo WAN, Shenzhen (CN); Yafei Yang, Shenzhen (CN)

(73) Assignee: DapuStor Corporation, Shenzhen (CN)

(21) Appl. No.: 19/089,521

(22) Filed: Mar. 25, 2025

Related U.S. Application Data
(63) Continuation of application No. PCT/CN2023/094015, filed on May 12, 2023.

(30) Foreign Application Priority Data
Sep. 30, 2022 (CN) 202211231769.5

(51) Int. Cl. G06F 3/06

(52) U.S. Cl. CPC G06F 3/0604; G06F 3/0655; G06F 3/0679

(57) ABSTRACT

A method for managing flash memory and a flash memory device are provided. By acquiring a logical word line address corresponding to each logic unit in at least one logic unit and looking up a mapping table according to the logical word line address corresponding to each logic unit, and determining a physical word line group corresponding to the logical word lines of each logic unit, in this application, the mapping table can be used to map the logical word lines and the physical word line groups, the physical word line group includes at least one physical word line, and the numbers of data pages included in at least two physical word lines are not exactly the same, and different types of flash memory particles are adapted to improve compatibility of the flash memory device with flash memory particles.

### CROSS-REFERENCE TO RELATED APPLICATIONS

The present application is a continuation of International Application No. PCT/CN2023/094015, filed on May 12, 2023, which claims the benefit of priority to Chinese Patent Application No. 202211231769.5 filed on Sep. 30, 2022. The entire contents of each of the above-referenced applications are expressly incorporated herein by reference.

### TECHNICAL FIELD

The application relates to the field of applications of storage devices, in particular to a method for managing flash memory and a flash memory device.

### BACKGROUND

Flash memory devices, such as Solid State Drives (SSD), are hard disks made of solid-state electronic storage chip arrays, including a control unit and a storage unit (FLASH chip or DRAM chip). At present, flash memory devices usually collect a piece of data and write it into the word line of a data block after mapping from a logical address to a physical address. However, due to the architecture process and other reasons, the sizes of word lines inside the data block are not uniform, that is, the numbers of data pages of word lines inside the data block are different. For example, some word lines include 1 data page, 2 data pages or 3 data pages, so that the algorithm for writing data into word lines needs to be improved, resulting in insufficient compatibility of flash memory devices with flash memory particles. Based on this, the prior art needs to be improved urgently.

### SUMMARY

Embodiments of the present application provide a method for managing flash memory and a flash memory device to improve compatibility of the flash memory device with flash memory particles.

In order to solve the above technical problems, embodiments of the present application provide the following technical solutions.

In a first aspect, embodiments of the present application provide a method for managing flash memory, which is applied to a flash memory device and the method includes the following steps:
acquiring a write request, where the write request includes physical address information and to-be-written data;
acquiring a logical word line address corresponding to each logic unit in at least one logic unit according to physical address information corresponding to the write request;
looking up a mapping table according to the address of the logical word line corresponding to each logic unit, and determining a physical word line group corresponding to the logical word lines of each logic unit, where the mapping table includes a mapping relationship between the logical word lines and the physical word line group, the physical word line group includes at least one physical word line, the numbers of data pages included in at least two physical word lines are not exactly the same, and each physical word line includes a plurality of data pages; and
writing to-be-written data into a physical word line corresponding to the physical word line group according to the physical word line group corresponding to the logical word line of each logic unit.

In some embodiments, the number of data pages corresponding to the physical word line with a largest serial number in a physical word line group is equal to the number of data pages of one logical word line.

In some embodiments, before acquiring a write request, the method further includes establishing a mapping table, including the following steps:
if a physical block of the flash memory device includes two types of physical word lines, namely a first physical word line and a second physical word line, then:
performing a mapping starting from the physical word line with the smallest serial number;
identifying whether the current physical word line is the first physical word line;
if yes, combining several consecutive first physical word lines into a first physical word line group and mapping the first physical word line group to a logical word line;
if no, determining that the current physical word line is a second physical word line, and mapping the current physical word line directly to one logical word line; and
traversing all physical word lines of a physical block,
where the first physical word line includes a first number of data pages, the second physical word line includes a second number of data pages, the second number is greater than the first number and the number of data pages of the logical word line is less than or equal to the number of data pages of the physical word line or the physical word line group corresponding to the logical word line, and the number of data pages of the logical word line is equal to the number of data pages corresponding to the physical word line with the largest serial number.

In some embodiments, establishing a mapping table further includes the following steps:
if a physical block of the flash memory device includes three types of physical word lines, namely a first physical word line, a second physical word line and a third physical word line, then:
performing a mapping starting from the physical word line with the smallest serial number;
identifying whether the current physical word line is the first physical word line, where the first physical word line includes a first number of data pages;
if yes, combining several consecutive first physical word lines into a first physical word line group and mapping the first physical word line group to a logical word line;
if no, further identifying whether the current physical word line is a second physical word line, where the second physical word line includes a second number of data pages, and the second number is greater than the first number;
if the current physical word line is the second physical word line, combining several consecutive second physical word lines into a second physical word line group and mapping the second physical word line group to a logical word line;
if the current physical word line is not the second physical word line, determining that the current physical word line is a third physical word line, and mapping the current physical word line directly to one logical word line; and
traversing all physical word lines of a physical block,
where the third physical word line includes a third number of data pages, the third number is greater than the second number and the number of data pages of the logical word line is less than or equal to the number of data pages of the physical word line or the physical word line group corresponding to the logical word line, and the number of data pages of the logical word line is equal to the number of data pages corresponding to the physical word line with the largest serial number.

In some embodiments, establishing a mapping table further includes the following steps:
if a physical block of the flash memory device includes N types of physical word lines, namely a first physical word line, a second physical word line, . . . the (N−1)^{th} physical word line and the N^{th} physical word line, then:
if the current physical word line is not the second physical word line, continuing to identify whether the current physical word line is the third physical word line;
if yes, combining several third physical word lines into one third physical word line group and mapping the one third physical word line group to one logical word line;
and the like, until it is identified whether the current physical word line is the (N−1)^{th} physical word line;
if the current physical word line is the (N−1)^{th} physical word line, combining several (N−1)^{th} physical word lines into one (N−1)^{th} physical word line group and mapping the one (N−1)^{th} physical word line group to one logical word line;
if the current physical word line is not the (N−1)^{th} physical word line, determining that the current physical word line is a (N−1)^{th} physical word line, and mapping the current physical word line directly to one logical word line; and
traversing all physical word lines of a physical block,
where N is a positive integer and greater than the third number, and the number of data pages of each logical word line is the same, and the number of data pages of the logical word line is less than or equal to the number of data pages of the physical word line or physical word line group corresponding to the logical word line, the logical word lines correspond one by one to the physical word lines with the maximum number of data pages, and the number of data pages of the logical word lines is equal to the number of data pages corresponding to the physical word line with the largest serial number.

In some embodiments, writing to-be-written data into a physical word line corresponding to the physical word line group according to the physical word line group corresponding to the logical word line of each logic unit includes the following steps:
writing data corresponding to each logic unit in the to-be-written data into the physical word line group corresponding to each logic unit in parallel, where:
if the physical word line group corresponding to the logic unit includes one physical word line, writing data in the to-be-written data corresponding to the logic unit into the physical word line; and
if the physical word line group corresponding to the logic unit includes at least two physical word lines, writing data in the to-be-written data corresponding to the logic unit into the at least two physical word lines.

In some embodiments, the method further includes the following steps:
if the physical word line group corresponding to the logic unit includes one physical word line, writing data in the to-be-written data corresponding to the logic unit into the physical word line and determining that the writing is completed; and
if the physical word line group corresponding to the logic unit includes at least two physical word lines, after writing data in the to-be-written data corresponding to the logic unit into the at least two physical word lines, filling invalid data into a remaining space of the physical word line group and determining that the writing is completed,
where the data volume of the to-be-written data is equal to the number of logic units in a die of the flash memory device multiplied by the number of data pages corresponding to one logic unit multiplied by the size of one data page.

In some embodiments, the physical address information includes an address of the die, an address of at least one logic unit, an address of a physical block, and a logical word line address.

In a second aspect, embodiments of the present application provide a method for managing flash memory, which is applied to a flash memory device and the method includes the following steps:
acquiring a read request, where the read request includes logical address information;
acquiring a logical word line address according to the logical address information corresponding to the read request;
looking up a mapping table according to the logical word line corresponding to the address of the logical word line, and determining a physical word line group corresponding to the logical word line, where the mapping table includes a mapping relationship between the logical word lines and the physical word line group, the physical word line group includes at least one physical word line, the numbers of data pages included in at least two physical word lines are not exactly the same, and each physical word line includes a plurality of data pages; and
reading data corresponding to a read request according to a physical word line address of the physical word line group.

In some embodiments, reading data corresponding to a read request according to a physical word line address of the physical word line group includes:
determining a data page address corresponding to a physical word line address according to the physical word line address and reading data corresponding to the data page address.

In some embodiments, a logical word line address includes a number of logical data pages, where the size of each logical data page is equal to the size of one physical data page, and the starting address of a logical data page is the address of a first mapped physical word line.

In a third aspect, embodiments of the present application provide a flash memory device, including: at least one processor; and
a memory communicatively connected to the at least one processor, where the memory stores instructions executable by the at least one processor, the instructions being executed by the at least one processor to enable the at least one processor to perform the method for managing flash memory according to the first aspect or the second aspect.

In a fourth aspect, embodiments of the present application further provide a non-volatile computer-readable storage medium; the non-volatile computer-readable storage medium stores computer-executable instructions; the computer-executable instructions are configured to enable a flash memory device to perform the method for managing flash memory according to the first aspect.

Embodiments of the present application have the following beneficial effects: Different from the prior art, a method for managing flash memory provided by embodiments of the present application is applied to a flash memory device, and the method includes the following steps: acquiring a write request, where the write request includes physical address information and to-be-written data; acquiring a logical word line address corresponding to each logic unit in at least one logic unit according to physical address information corresponding to the write request; looking up a mapping table according to the address of the logical word line corresponding to each logic unit, and determining a physical word line group corresponding to the logical word lines of each logic unit, where the mapping table includes a mapping relationship between the logical word lines and the physical word line group, the physical word line group includes at least one physical word line; and writing to-be-written data into a physical word line corresponding to the physical word line group according to the physical word line group corresponding to the logical word line of each logic unit.

On the one hand, by acquiring a logical word line address corresponding to each logic unit in at least one logic unit and looking up a mapping table according to the address of the logical word line corresponding to each logic unit, and determining a physical word line group corresponding to the logical word lines of each logic unit, in the present application, the mapping table can be used to map the logical word lines and the physical word line groups, the physical word line group includes at least one physical word line, and the numbers of data pages included in at least two physical word lines are not exactly the same, in the present application, different types of flash memory particles are adapted to improve compatibility of the flash memory device with flash memory particles;

On the other hand, by writing to-be-written data into a physical word line corresponding to the physical word line group according to the physical word line group corresponding to the logical word line of each logic unit, in the present application, the stability of data storage is improved.

### BRIEF DESCRIPTION OF DRAWINGS

One or more embodiments are exemplarily illustrated by the figures in the corresponding drawings. These exemplary descriptions do not constitute a limitation to the embodiments. Elements with the same reference numerals in the drawings are denoted as similar elements. Unless otherwise stated, the figures in the drawings do not constitute a scale limitation.

FIG. 1 is a schematic diagram illustrating the structure of a flash memory device according to embodiments of the present application;

FIG. 2 is a schematic diagram illustrating the structure of a firmware system of a flash memory device according to embodiments of the present application;

FIG. 3 is a schematic diagram of a NAND particle according to embodiments of the present application;

FIG. 4 is a schematic diagram of another NAND particle according to embodiments of the present application;

FIG. 5 is a schematic flow chart of a method for managing flash memory according to embodiments of the present application;

FIG. 6 is a schematic diagram of mapping between logical word lines and physical word line groups according to embodiments of the present application;

FIG. 7 is a schematic flow chart of establishing a mapping table according to embodiments of the present application;

FIG. 8 is another schematic flow chart of establishing a mapping table according to embodiments of the present application;

FIG. 9 is further another schematic flow chart of establishing a mapping table according to embodiments of the present application;

FIG. 10 is a detailed schematic flow chart of S504 in FIG. 5;

FIG. 11 is a schematic flow chart of writing data into a flash memory according to embodiments of the present application;

FIG. 12 is a schematic flow chart of another method for managing flash memory according to embodiments of the present application;

FIG. 13 is a detailed schematic flow chart of S1204 in FIG. 12;

FIG. 14A is a schematic diagram of a mapping relationship between logical word lines and physical word lines according to embodiments of the present application;

FIG. 14B is a schematic diagram of another mapping relationship between logical word lines and physical word lines according to embodiments of the present application;

FIG. 15 is a schematic flow chart of reading data from a flash memory according to embodiments of the present application; and

FIG. 16 is a schematic diagram illustrating the structure of a storage device according to embodiments of the present application.

### DETAILED DESCRIPTION

In order to make the purpose, technical solution, and advantages of the present application clearer, the following detailed description is provided with reference to the accompanying drawings and embodiments. It should be understood that the specific embodiments described herein are intended to explain the present application and not to limit it. Based on embodiments of the present application, all other embodiments obtained by ordinary persons skilled in the art without creative efforts shall fall within the protection scope of the present application.

It should be noted that, if there is no conflict, the various features in embodiments of the present application can be combined with each other and are within the protection scope of the present application. In addition, although functional block division is shown in the apparatus schematic diagram and a logical order is presented in the flow chart, in some cases, the steps shown or described may be performed in an order different from the block division in the apparatus or the sequence in the flow chart. Furthermore, the terms “first,” “second,” “third” and so on used in the present application do not limit the data and execution order but are merely used to distinguish between items that are the same or similar in function and effect.

Before the detailed description of the present application, the nouns and terms involved in embodiments of the present application are explained. The following interpretations apply to the nouns and terms involved in embodiments of the present application:

(1) Word line (WL), which is the basic writing unit of NAND. The number of data pages (Page) contained in each word line varies depending on the NAND particles. For example, one word line may contain one data page, or one word line may contain two data pages, or one word line may contain more than three data pages.

(2) Physical word line (physical WL) refers to the actual word line in the NAND.

(3) Logical word line (logical WL, Log_WL) refers to a word line that is mapped to a physical word line. In embodiment of the present application, one logical word line corresponds to one or more than two physical word lines.

The technical solution of the present application will be described in detail below with reference to the drawings in the specification.

FIG. 1 is a schematic diagram illustrating the structure of a flash memory device according to embodiments of the present application.

As shown in FIG. 1, the flash memory device 100 includes a flash medium 110 and a controller 120 connected to the flash medium 110. The flash memory device 100 is communicatively connected with a host 200 in a wired or wireless manner to implement data interaction.

The flash medium 110, as a storage medium of the flash memory device 100, is also called flash memory, Flash, Flash memory or Flash particle; it belongs to memory devices and is a non-volatile memory that can store data for a long time even without current supply; its storage characteristics are equivalent to those of hard disks, so that the flash medium 110 can become the basis of storage media of various portable digital devices.

The controller 120 includes a data converter 121, a processor 122, a buffer 123, a flash memory controller 124 and an interface 125.

The data converter 121 is connected to the processor 122 and the flash memory controller 124, respectively. The data converter 121 is configured to convert binary data into hexadecimal data and convert hexadecimal data into binary data. In some embodiments, when the flash memory controller 124 writes data into the flash medium 110, binary data to be written is converted into hexadecimal data by the data converter 121 and then written into the flash medium 110. When the flash memory controller 124 reads data from the flash medium 110, hexadecimal data stored in the flash medium 110 is converted into binary data by the data converter 121 and then the converted data is read from a binary data page register. In which, the data converter 121 may comprise a binary data register and a hexadecimal data register. The binary data register is configured to store the data converted from hexadecimal to binary, and the hexadecimal data register is configured to store the data converted from binary to hexadecimal.

The processor 122 is respectively connected with the data converter 121, the buffer 123, the flash memory controller 124 and the interface 125, in which the processor 122 can be connected with the data converter 121, the buffer 123, the flash memory controller 124 and the interface 125 through a bus or other means; the processor is configured to run non-volatile software programs, instructions and modules stored in the buffer 123, thereby implementing any method embodiment of the present application.

The buffer 123 is mainly configured to buffer read/write instructions sent by the host 200 and read data or to-be-written data obtained from the flash medium 110 according to the read/write instructions sent by the host 200.

A flash memory controller 124, connected to the flash medium 110, the data converter 121, the processor 122, and the buffer 123, is configured to access the back-end flash medium 110 and managing various parameters and data I/O of the flash medium 110; or, to provide an interface and protocol for access, implement the corresponding SAS/SATA target protocol end or NVMe protocol end, acquire I/O instructions issued by the host 200, decode and generate internal private data results for execution; or, to be responsible for the core processing of the flash translation layer (FTL).

The interface 125, connected to the host 200, the data converter 121, the processor 122, and the buffer 123, is configured to receive data sent by the host 200 or receive data sent by the processor 122 to facilitate data transmission between the host 200 and the processor 122. The interface 125 can be a SATA-2 interface, a SATA-3 interface, a SAS interface, an MSATA interface, a PCI-E interface, an NGFF interface, a CFast interface, an SFF-8639 interface, or an M.2 NVMe/SATA protocol.

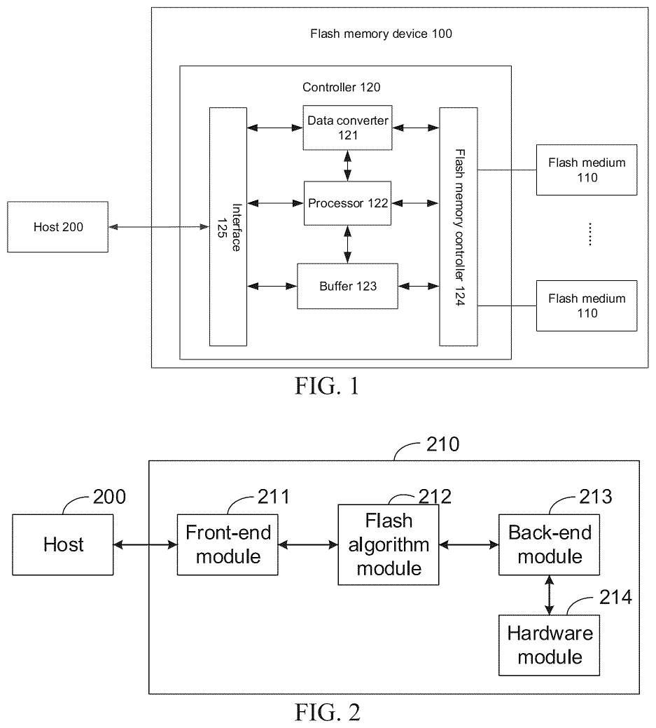

FIG. 2 is a schematic diagram illustrating the structure of a firmware system of a flash memory device according to embodiments of the present application.

It can be understood that the flash memory controller of the flash memory device includes a firmware system, and the firmware system is configured to connect a host (HOST) and a flash array to implement data IO processing.

As shown in FIG. 2, the firmware system 210 includes:
a front-end (FE) module 211, configured to obtain host commands so as to generate IO operations, where the front-end module is further configured to take charge of communication protocols with a host (Host), parse host commands and SSD commands and perform other operations;
a flash algorithm module 212, i.e. a flash translation layer (FTL), configured to perform mapping processing on the IO operations so as to determine a delivered flash array,
where the flash algorithm module 212 sends an IO operation to a back-end (BE) module 213 of the flash memory controller, so that the back-end module 213 of the flash memory controller receives the IO operation sent by the flash algorithm module 212;
a back-end (BE) module 213, connected to the flash algorithm module 212, configured to receive IO operations sent by the flash algorithm module 212, so as to control the hardware module 214 to perform read/write/erase operations on the flash array;
a hardware module 214 (HW Op Nand Mode), which refers to a module for operating the Flash memory; it is connected to the back-end module 213 and controlled by the back-end module 213, so as to operate the Flash memory; for instance, according to the IO operation, an operation is performed on the corresponding flash array or flash medium, that is, to complete the operation processing of data to Flash memory, and the operations comprise read operation, write operation or erase operation.

In which, after acquiring a host command, the front-end module 211 processes it to generate an IO operation and sequentially passes through the flash algorithm module 212, the back-end module 213 and the hardware module 214 to operate the flash array. For example, when a host reads data, the host (Host) sends a host command to the flash memory device (device), and the front-end (FE) module 211 of the flash memory device receives the host command, processes it and distributes it to the flash algorithm module 212; after receiving the command, the flash algorithm module 212 performs logic-to-physical conversion processing, and then sends a request NAND read operation to the back-end (BE) module 213; after receiving the request, the back-end module 213 sends a hardware command to the hardware module (214) and performs NAND processing in parallel.

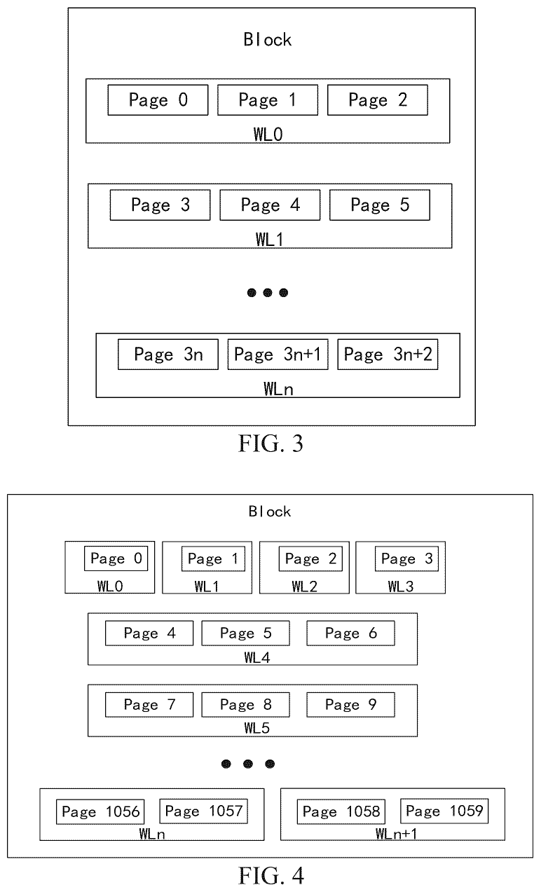

FIG. 3 is a schematic diagram of a NAND particle according to embodiments of the present application.

As shown in FIG. 3, a physical block (Block) includes a plurality of word lines (WL), for example, word line 0 (WL0), word line 1 (WL1), . . . and word line n (WLn). It is understood that the word line refers to an actual physical word line in a flash memory device.

In which, each word line includes 3 data pages (Page); for instance, word line 0 includes data page 0 (Page 0), data page 1 (Page 1), and data page 2 (Page 2); word line 1 includes data page 3 (Page 3), data page 4 (Page 4), and data page 5 (Page 5); word line n includes data page 3n (Page 3n), data page 3n+1 (Page 3n+1), and data page 3n+2 (Page 3n+2).

Obviously, the size of each word line in the block of the NAND particle is the same, including 3 word lines; in this case, the back-end module can determine the address to be written and the volume of data to be written, so as to write a fixed volume of to-be-written data into a plurality of logic units of the NAND particle in parallel.

However, for NAND particles with different sizes of word lines, refer further to FIG. 4, which is a schematic diagram of another NAND particle according to embodiments of the present application;

As shown in FIG. 4, for one physical block (Block), there are at least two word lines (WL) having different sizes, i.e., the numbers of data pages included in at least two word lines are different. For example: word line 0 (WL0), word line 1 (WL1), word line 2 (WL2) and word line 3 (WL3) all comprise a data page, which are data page 0 (Page 0), data page 1 (Page 1), data page 2 (Page 2), and data page 3 (Page 3), respectively; word line 4 (WL4) includes 3 data pages, i.e., data page 4 (Page 4), data page 5 (Page 5), and data page 6 (Page 6); word line 5 (WL5) further includes 3 data pages, namely data page 7 (Page 7), data page 8 (Page 8), and data page 9 (Page 9); word line n (WLn) includes two data pages, namely data page 1056 (Page 1056) and data page 1057 (Page 1057), and word line n+1 (WLn+1) further includes two data pages, namely data page 1058 (Page 1058) and data page 1059 (Page 1059).

In this case, if the to-be-written data with a fixed volume of data is still written into a plurality of logic units of the NAND particle in parallel, due to different sizes of word lines in the physical block, the back-end module cannot determine an address to be written and also cannot determine the volume of data that can be written, resulting in failure to support this type of NAND particle.

In view of this, the present application realizes NAND particle that supports different numbers of data pages included in physical word lines by mapping physical word lines with logical word lines.

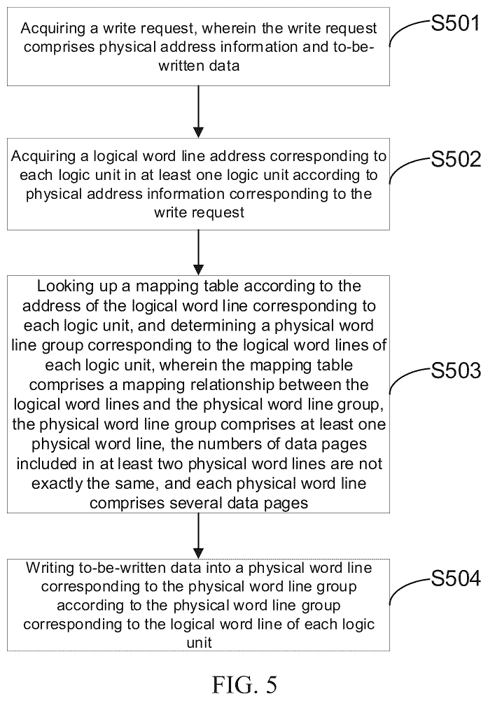

FIG. 5 is a schematic flow chart of a method for managing flash memory according to embodiments of the present application.

The method for managing flash memory is applied to a flash memory device. The flash memory device includes a flash memory controller, and the flash memory controller includes a firmware system, the and the firmware system includes a front-end module, a flash algorithm module, a back-end module, and a hardware module.

As shown in FIG. 5, the method for managing flash memory includes the following steps:
S501, acquiring a write request, where the write request includes physical address information and to-be-written data;
in some embodiments, the write request is sent by the host to the flash memory device; in some embodiments, the front-end module receives the write request sent by the host and sends the to-be-written data of fixed volume to the flash algorithm module for writing; after receiving the write request sent by the front-end module, the flash algorithm module maps the logical address with the physical address and forwards the write request to the back-end module, the back-end module receives the write request and writes the to-be-written data into the flash memory, where the write request includes physical address information and to-be-written data.

In embodiments of the present application, the physical address information includes an address of a die (Die), an address of at least one logic unit (Plane), an address of a physical block (Block) and a logical word line address (Log_WL address).

In embodiments of the present application, the to-be-written data is related to the number of logic units in one die of the flash memory device, and in some embodiments, the to-be-written data is positively correlated with the number of logic units in one die of the flash memory device. It can be understood that one die of the flash memory device includes at least one logic unit, where the data volume corresponding to the to-be-written data by the front-end (FE) module is related to the number of logic units (Plane). For example, for NAND particles with 4 planes, assuming that the size of one physical word line (WL) is 3 data pages (Page), the size of the to-be-written data P of the front-end (FE) module is: P=1 WL*4 planes=4 WLs=4*3 pages=data volume of 12 pages; similarly, for 2 planes NAND particles, the size of the to-be-written data P is: P=2*3=data volume of 6 pages.
S502: acquiring a logical word line address corresponding to each logic unit in at least one logic unit according to physical address information corresponding to the write request.

In some embodiments, the physical address information includes an address of a die (Die), an address of at least one logic unit (Plane), an address of a physical block (Block), and a logical word line address (Log_WL address). Since the write request corresponds to a plurality of logic units (Plane), the logical word line address (Log_WL address) corresponding to each logic unit in the at least one logic unit is acquired from the physical address information corresponding to the write request.
S503: looking up a mapping table according to the address of the logical word line corresponding to each logic unit, and determining a physical word line group corresponding to the logical word lines of each logic unit, where the mapping table includes a mapping relationship between the logical word lines and the physical word line group, the physical word line group includes at least one physical word line, the numbers of data pages included in at least two physical word lines are not exactly the same, and each physical word line includes a plurality of data pages; and
in some embodiments, looking up a mapping table according to the logical word line address corresponding to each logical unit, and determining a physical word line group corresponding to the physical word line of each logical unit.

In embodiments of the present application, the mapping table is configured to characterize a mapping relationship between logical word lines and physical word line groups. The mapping relationship between logical word lines and physical word line groups includes a mapping relationship among logical word lines, logical word line addresses, physical word line groups, addresses of physical word line groups, and addresses of each physical word line in the physical word line groups.

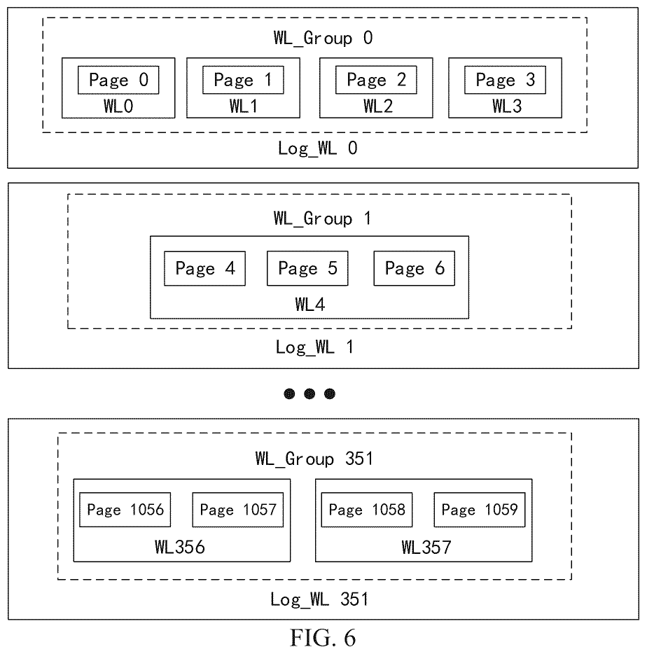

FIG. 6 is a schematic diagram of mapping between logical word lines and physical word line groups according to embodiments of the present application.

As shown in FIG. 6, one logical word line (Log_WL) maps one physical word line group (WL_Group); one physical word line group includes at least one physical word line (WL), for instance, the logical word line 0 (Log_WL 0) maps the physical word line group 0 (WL_Group 0), and the physical word line group 0 (WL_Group 0) includes four physical word lines, i.e., physical word line 0-physical word line 3 (WL0-WL3), respectively, where each physical word line includes one data page, i.e., data page 0-3 (Page 0-3) respectively.

The logical word line 1 (Log_WL 1) maps the physical word line group 1 (WL_Group 1), the physical word line group 1 (WL_Group 1) includes one physical word line 4 (WL4), and the physical word line 4 (WL4) includes three data pages, i.e., data page 4-data page 6 (Page 4-6), respectively.

A logical word line 351 (Log_WL 351) maps a physical word line group 351 (WL_Group 351); the physical word line group 351 (WL_Group 351) includes two physical word lines, namely physical word line 356 (WL356) and physical word line 357 (WL357); each physical word line includes two data pages, for instance, physical word line 356 (WL356) includes data page 1056 (Page 1056) and data page 1057 (Page 1057), and physical word line 357 (WL357) includes data page 1058 (Page 1058) and data page 1059 (Page 1059).

It should be noted that each physical word line group may comprise one or more than two physical word lines, and the number of physical word lines in each group is determined by the number of physical word lines in a specific NAND particle.

It can be understood that, in order to look up a mapping table, the mapping table is generally established before acquiring the write request, i.e., the mapping table is established prior to acquiring the write request.

In embodiments of the application, the number of data pages in a logical word line is equal to the number of data pages in the physical word line with the largest serial number.

It can be understood that, in a flash memory device, one die (Die) may comprise a plurality of logic units (Plane), one logic unit (Plane) may comprise a plurality of physical blocks (Block), and one physical block (Block) may comprise two, three or more than four kinds of physical word lines. Therefore, the statement for establishing a mapping table is made respectively for one physical block including two, three or more than four kinds of physical word lines.

### (1) One Physical Block Includes Two Kinds of Physical Word Lines

In some embodiments, establishing a mapping table includes the following steps:
if a physical block of the flash memory device includes two types of physical word lines, namely a first physical word line and a second physical word line, then:
performing a mapping starting from the physical word line with the smallest serial number;
identifying whether the current physical word line is the first physical word line;
if yes, combining several consecutive first physical word lines into a first physical word line group and mapping the first physical word line group to a logical word line;
if no, determining that the current physical word line is a second physical word line, and mapping the current physical word line directly to one logical word line; and
traversing all physical word lines of a physical block,
where the first physical word line includes a first number of data pages, the second physical word line includes a second number of data pages, the second number is greater than the first number and the number of data pages of the logical word line is less than or equal to the number of data pages of the physical word line or the physical word line group corresponding to the logical word line.

For example: One logical word line corresponds to one physical word line, and in this case, the number of data pages of the physical word line is 3, then the number of data pages of the logical word line is 3; or, one logical word line corresponds to one physical word line group, the physical word line group includes two physical word lines, and the numbers of data pages corresponding to the two physical word lines are 2 and 3, respectively, in this case, the number of data pages of the physical word line group is 5, and the number of data pages of the logical word line is 3. In some embodiments, the number of data pages of a logical word line is equal to the number of data pages of the physical word line with the largest serial number. As mentioned above, if the physical word line with the largest serial number is a physical word line with 3 data pages, then the number of data pages of the logical word line at the moment is 3.

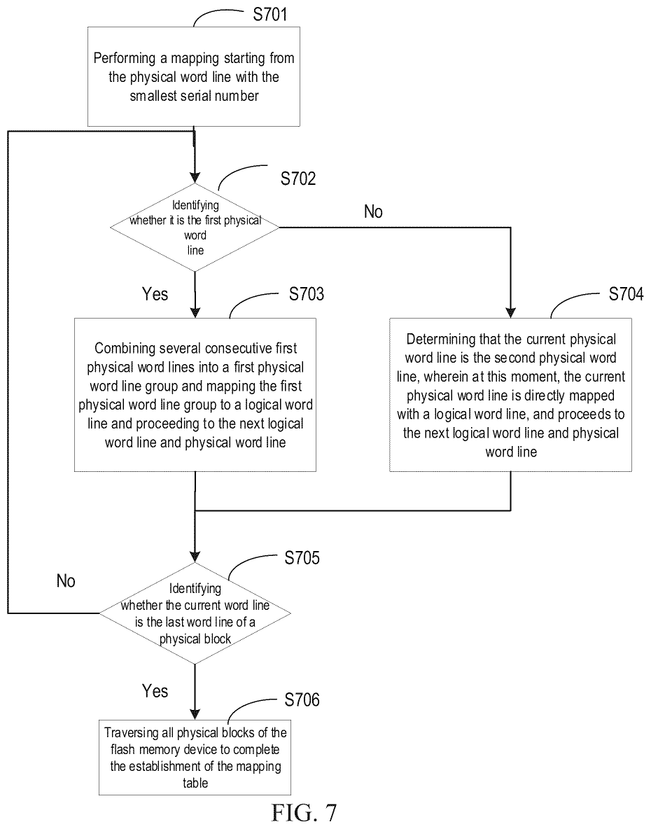

FIG. 7 is a schematic flow chart of establishing a mapping table according to embodiments of the present application.

As shown in FIG. 7, the process of establishing a mapping table includes the following steps:
S701, performing a mapping starting from the physical word line with the smallest serial number;
in some embodiments, assuming that there are n physical word lines in a physical block and each physical word line corresponds to a serial number, the numbers of the physical word lines start from the serial number 0 until the last physical word line n−1. It can be understood that the mapping is performed from the physical word line with the smallest serial number to the physical word line with the largest serial number.
S702, identifying whether it is the first physical word line;
in some embodiments, if one physical block includes two types of physical word lines, the two types of physical word lines are respectively named as a first physical word line and a second physical word line, where the first physical word line includes a first number of data pages, the second physical word line includes a second number of data pages, and the second number is greater than the first number and is the maximum number of data pages for one physical word line. For example, the first number is 1 and the second number is 2; or, the first number is X and the second number is X+M, where X and M are positive integers.

If the current physical word line is the first physical word line, proceed to S703;
if the current physical word line is not the first physical word line, it is determined that the current physical word line is the second physical word line, and in this case, proceed to S704;
S703, combining several consecutive first physical word lines into a first physical word line group and mapping the first physical word line group to a logical word line and proceeding to the next logical word line and physical word line;
in some embodiments, if the current physical word line is the first physical word line, combining several consecutive first physical word lines into a first physical word line group, where each physical word line in the first physical word line group is the first physical word line, and the number of data pages contained by all physical word lines in the first physical word line group is not less than the number of data pages contained by a second physical word line. For example, assuming that the first physical word line contains 1 data page and the second physical word line contains 2 data pages, more than two consecutive first physical word lines are combined into a first physical word line group; in this case, the number of data pages contained in all physical word lines in one first physical word line group is equal to or greater than 2, i.e., equal to or greater than the number of data pages contained in one second physical word line.

It can be understood that, proceeding to the next logical word line and physical word line refers to incrementing the serial number of the logical word line by one and correspondingly incrementing the serial number of the physical word line by n, where n is the number of the first physical word lines in the first physical word line group; for example, if the number of the first physical word lines in the first physical word line group is two, the serial number of the physical word line is incremented by two.

Moreover, after proceeding to the next logical word line and physical word line, proceed to S705: identifying whether the current word line is the last word line of a physical block, that is, identifying whether the current physical word line is the last physical word line of the current physical block, that is, identifying whether all the physical word lines of the current physical block have been traversed, if yes, proceed to S706;
if no, proceed to the next physical word line, take the next physical word line as the current physical word line, and perform the same processing on the current physical word line, i.e., identifying whether the current physical word line is the first physical word line; if yes, proceed to S703; if no, proceed to S704 and so on until all physical word lines of the current block are traversed.
S704, determining that the current physical word line is the second physical word line, where in this case, the current physical word line is directly mapped with a logical word line, and proceeds to the next logical word line and physical word line;
S705, identifying whether the current word line is the last word line of a physical block;
in some embodiments, identifying whether the current physical word line is the last physical word line of the physical block, that is, identifying whether all the physical word lines of the current physical block have been traversed, that is, identifying whether all the physical word lines of the current physical block have been mapped, if yes, proceeding to S706; if no, returning to S702.
S706, traversing all physical blocks of the flash memory device to complete the establishment of the mapping table.

In some embodiments, after traversing all the physical word lines of the current physical block, map the next physical block until all the blocks of the flash memory device are traversed to complete the establishment of the mapping table. It can be understood that the operation on each physical block is the same as the above-mentioned operation, which will not be repeated here.

### (2) One Physical Block Includes Three Kinds of Physical Word Lines

In some embodiments, establishing a mapping table includes the following steps:
if a physical block of the flash memory device includes three types of physical word lines, namely a first physical word line, a second physical word line and a third physical word line, then:
performing a mapping starting from the physical word line with the smallest serial number;
identifying whether the current physical word line is the first physical word line, where the first physical word line includes a first number of data pages;
if yes, combining several consecutive first physical word lines into a first physical word line group and mapping the first physical word line group to a logical word line;
if no, further identifying whether the current physical word line is a second physical word line, where the second physical word line includes a second number of data pages, and the second number is greater than the first number;
if the current physical word line is the second physical word line, combining several consecutive second physical word lines into a second physical word line group and mapping the second physical word line group to a logical word line;
if the current physical word line is not the second physical word line, determining that the current physical word line is a third physical word line, and mapping the current physical word line directly to one logical word line; and
traversing all physical word lines of a physical block,
where the third physical word line includes a third number of data pages, the third number is greater than the second number and the number of data pages of the logical word line is less than or equal to the number of data pages of the physical word line or the physical word line group corresponding to the logical word line, and the number of data pages of the logical word line is equal to the number of data pages corresponding to the physical word line with the largest serial number.

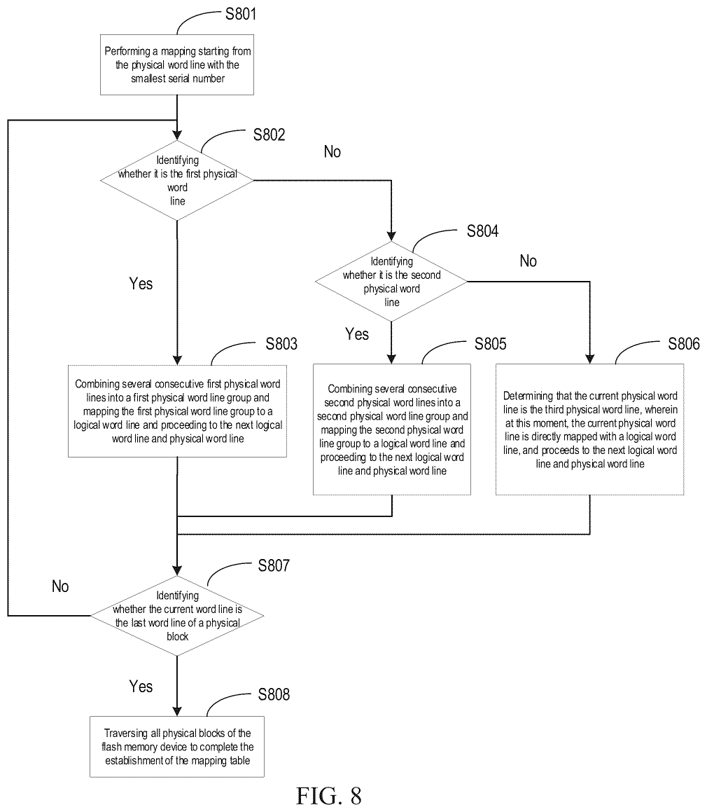

FIG. 8 is another schematic flow chart of establishing a mapping table according to embodiments of the present application.

As shown in FIG. 8, the process of establishing a mapping table includes the following steps:
S801, performing a mapping starting from the physical word line with the smallest serial number;
in some embodiments, assuming that there are n physical word lines in a physical block and each physical word line corresponds to a serial number, the numbers of the physical word lines start from the serial number 0 until the last physical word line n−1. It can be understood that the mapping is performed from the physical word line with the smallest serial number to the physical word line with the largest serial number.
S802, identifying whether it is the first physical word line;
in some embodiments, if one block includes three types of physical word lines, the three types of physical word lines are named as a first physical word line, a second physical word line and a third physical word line respectively, where the first physical word line includes a first number of data pages, the second physical word line includes a second number of data pages, the third physical word line includes a third number of data pages, and the second number is greater than the first number, the third number is greater than the second number, and the number of data pages of the logical word line is less than or equal to the number of data pages of the physical word line or the physical word line group corresponding to the logical word line. Further, the number of data pages for a logical word line is equal to the number of data pages corresponding to the physical word line with the largest serial number.

For example, the first number is 1, the second number is 2, and the third number is 3; or, the first number is X, the second number is X+M, and the third number is X+M+N, where X, M, and N are positive integers. For example: One logical word line corresponds to one physical word line, and in this case, the number of data pages of the physical word line is 3, then the number of data pages of the logical word line is 3; or, one logical word line corresponds to one physical word line group, the physical word line group includes two physical word lines, and both numbers of data pages corresponding to the two physical word lines are 2, in this case, the number of data pages of the physical word line group is 4, and the number of data pages of the logical word line is 3. In some embodiments, the number of data pages of a logical word line is equal to the number of data pages of the physical word line with the largest serial number. As mentioned above, if the physical word line with the largest serial number is a physical word line with 3 data pages, then the number of data pages of the logical word line at the moment is 3.

If the current physical word line is the first physical word line, proceed to S803;
if the current physical word line is not the first physical word line, it is determined that the current physical word line is the second physical word line, and in this case, proceed to S804;
S803, combining several consecutive first physical word lines into a first physical word line group and mapping the first physical word line group to a logical word line and proceeding to the next logical word line and physical word line;
in some embodiments, if the current physical word line is the first physical word line, combining several consecutive first physical word lines into a first physical word line group, where each physical word line in the first physical word line group is the first physical word line, and the number of data pages contained by all physical word lines in the first physical word line group is not less than the number of data pages contained by a third physical word line. For example, assuming that the first physical word line contains 1 data page, the second physical word line contains 2 data pages and the third physical word line contains 3 data pages, more than three or four consecutive first physical word lines are combined into a first physical word line group; in this case, the number of data pages contained in all physical word lines in one first physical word line group is equal to or greater than 3, i.e., equal to or greater than the number of data pages contained in one third physical word line.

It can be understood that, proceeding to the next logical word line and physical word line refers to incrementing the serial number of the logical word line by one and correspondingly incrementing the serial number of the physical word line by n, where n is the number of the first physical word lines in the first physical word line group; for example, if the number of the first physical word lines in the first physical word line group is four, the serial number of the physical word line is incremented by four.
S804, identifying whether it is the second physical word line;
in some embodiments, identifying whether the current physical word line is a second physical word line, if yes, proceed to S805; if no, proceed to S806;
S805, combining several consecutive second physical word lines into a second physical word line group and mapping the second physical word line group to a logical word line and proceeding to the next logical word line and physical word line;
in some embodiments, if the current physical word line is the second physical word line, combining several consecutive second physical word lines into a second physical word line group, where all physical word lines in the second physical word line group are second physical word lines, and the number of data pages contained by all physical word lines in the second physical word line group is not less than the number of data pages contained by a third physical word line. For example, assuming that the first physical word line contains 1 data page, the second physical word line contains 2 data pages and the third physical word line contains 3 data pages, two consecutive second physical word lines are combined into a second physical word line group; in this case, the number of data pages contained in all physical word lines in one second physical word line group is 4, greater than the number of data pages contained in one third physical word line.

It can be understood that, proceeding to the next logical word line and physical word line refers to incrementing the serial number of the logical word line by one and correspondingly incrementing the serial number of the physical word line by n, where n is the number of the second physical word lines in the second physical word line group; for example, if the number of the second physical word lines in the second physical word line group is two, the serial number of the physical word line is incremented by two.
S806, determining that the current physical word line is the third physical word line, where in this case, the current physical word line is directly mapped with a logical word line, and proceeds to the next logical word line and physical word line;
in some embodiments, if the current physical word line is not the second physical word line, determine that the current physical word line is the third physical word line, in this case, the current third physical word line is treated as a third physical word line group, the third physical word line group includes only one third physical word line, and this third physical word line group is mapped with a logical word line to proceed to the next logical word line and physical word line.

It can be understood that, since the third physical word line group includes only a third physical word line, proceeding to the next logical word line refers to incrementing the serial number of the logical word line by one, and proceeding to the next physical word line refers to incrementing the serial number of the physical word line by one.
S807, identifying whether the current physical word line is the last word line of a physical block;
in some embodiments, identifying whether the current physical word line is the last physical word line of the physical block, that is, identifying whether all the physical word lines of the current physical block have been traversed, that is, identifying whether all the physical word lines of the current physical block have been mapped, if yes, proceeding to S808; if no, returning to S802.
S808, traversing all physical blocks of the flash memory device to complete the establishment of the mapping table.

In some embodiments, after traversing all the physical word lines of the current physical block, map the next physical block until all the blocks of the flash memory device are traversed to complete the establishment of the mapping table. It can be understood that the operation on each physical block is the same as the above-mentioned operation, which will not be repeated here.

Table 1 below is a mapping table obtained by mapping one physical block including three types of physical word lines.

TABLE 1

| Logical | | | | | |
|---|---|---|---|---|---|
| word line | Physical word line | | | | Spliced or not |
| Log_WL 0 | WL0 (Page0) | WL1 | WL2 | WL3 | Spliced Log_WL |
| | | (Page1) | (Page2) | (Page3) | |
| Log_WL 1 | WL4 (Page4/ | | | | Unspliced Log_WL |
| | Page5/Page6) | | | | |
| Log_WL 2 | WL5 (Page7/ | | | | Unspliced Log_WL |
| | Page8/Page9) | | | | |
| Log_WL 3 | WL6 (Page10/ | | | | Unspliced Log_WL |
| | Page11/Page12) | | | | |
| . . . | . . . | | | | Unspliced Log_WL |
| Log_WL | WL352 | WL353 | | | Spliced Log_WL |
| 349 | (Page1048/ | (Page1050/ | | | |
| | Page1049) | Page1051) | | | |
| Log_WL | WL354 | WL355 | | | Spliced Log_WL |
| 350 | (Page1052/ | (Page1054/ | | | |
| | Page1053) | Page1055) | | | |
| Log_WL | WL356 | WL357 | | | Spliced Log_WL |
| 351 | (Page1056/ | (Page1058/ | | | |
| | Page1057) | Page1059) | | | |
| Log_WL | WL358 | WL359 | | | Spliced Log_WL |
| 352 | (Page1060/ | (Page1062/ | | | |
| | Page1061) | Page1063) | | | |
| Log_WL | WL360 | | | | Unspliced Log_WL |
| 353 | (Page1064/ | | | | |
| | Page1065/ | | | | |
| | Page1066) | | | | |
| Log_WL | WL361 | | | | Unspliced Log_WL |
| 354 | (Page1067/ | | | | |
| | Page1068/ | | | | |
| | Page1069) | | | | |
| Log_WL | WL362 | | | | Unspliced Log_WL |
| 355 | (Page1070/ | | | | |
| | Page1071/ | | | | |
| | Page1072) | | | | |
| . . . | | | | | Unspliced Log_WL |
| Log_WL | WL708 | WL709 | WL710 | WL711 | Spliced Log_WL |
| 701 | (Page2108) | (Page2109) | (Page2110) | (Page2111) | |

(3) One Physical Block Includes Four or More than Four Kinds of Physical Word Lines

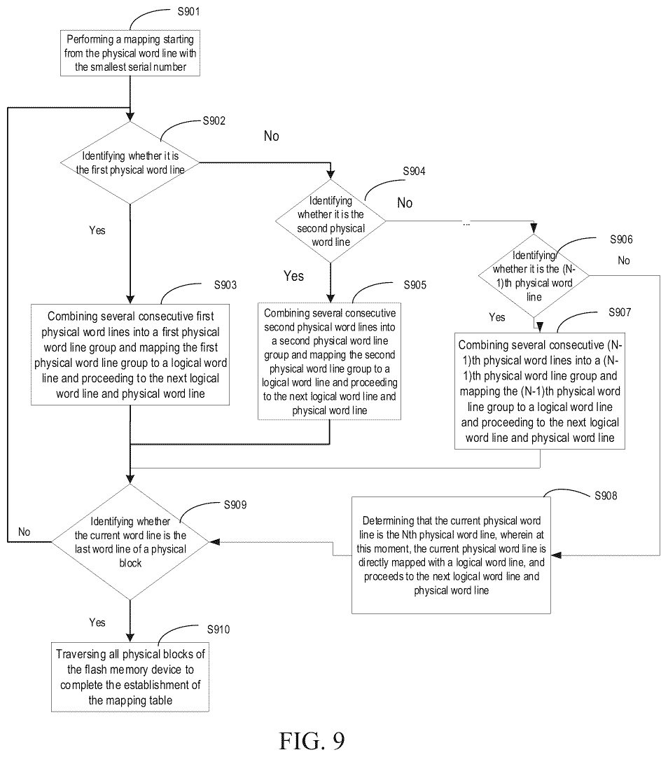

Referring further to FIG. 9, which is another schematic flow chart of establishing a mapping table according to embodiments of the present application.

As shown in FIG. 9, the process of establishing a mapping table includes the following steps:
S901, performing a mapping starting from the physical word line with the smallest serial number;
in some embodiments, assuming that there are n physical word lines in a physical block and each physical word line corresponds to a serial number, the numbers of the physical word lines start from the serial number 0 until the last physical word line n−1. It can be understood that the mapping is performed from the physical word line with the smallest serial number to the physical word line with the largest serial number.
S902, identifying whether it is the first physical word line;
in some embodiments, if one physical block includes N kinds of physical word lines, N is a positive integer and N>4, the N kinds of physical word lines are named as the first physical word line, the second physical word line, . . . the N^{th} physical word line, where the first physical word line includes the first number of data pages, the second physical word line includes the second number of data pages, . . . the N^{th} physical word line includes the N^{th} number of data pages, and the second number is greater than the first number, the third number is greater than the second number, . . . the N^{th} number is greater than the (N−1)^{th} number, and the number of data pages of each logical word line is the same, and the number of data pages of the logical word line is less than or equal to the number of data pages of the physical word line or physical word line group corresponding to the logical word line, the logical word lines correspond one by one to the physical word lines with the maximum number of data pages, and the number of data pages of the logical word lines is equal to the number of data pages corresponding to the physical word line with the largest serial number.

For example, the first number is 1, the second number is 2, and the third number is 3, which are gradually increased until the N^{th} number is T^{th}, where T is a positive integer.

Assuming that N=5, in this case, the first number is 1, the second number is 2, the third number is 3, the fourth number is 4, and the fifth number is 5, then: one logical word line corresponds to one physical word line, in this case, the number of data pages of the physical word lines is 5, and the number of data pages of the logical word lines is 5; or, one logical word line corresponds to one physical word line group, the physical word line group includes three physical word lines, the numbers of data pages corresponding to the three physical word lines are 2, 2 and 2, respectively, in this case, the number of data pages of the physical word line group is 6, and the number of data pages of the logical word lines is 5. In some embodiments, the number of data pages of a logical word line is equal to the number of data pages of the physical word line with the largest serial number. As mentioned above, if the physical word line with the largest serial number is a physical word line with 5 data pages, then the number of data pages of the logical word line at the moment is 5.

If the current physical word line is the first physical word line, proceed to S903;
if the current physical word line is not the first physical word line, it is determined that the current physical word line is the second physical word line, and in this case, proceed to S904;
S903, combining several consecutive first physical word lines into a first physical word line group and mapping the first physical word line group to a logical word line and proceeding to the next logical word line and physical word line;
in some embodiments, if the current physical word line is the first physical word line, combining several consecutive first physical word lines into a first physical word line group, where each physical word line in the first physical word line group is the first physical word line, and the number of data pages contained by all physical word lines in the first physical word line group is not less than the number of data pages contained by a N^{t}h physical word line. For example, assuming that the first physical word line includes 1 data page, the second physical word line includes 2 data pages, and the third physical word line includes 3 data pages, . . . and the N^{th} physical word line includes N data pages, then consecutive N or more than N first physical word lines are combined into a first physical word line group, in this case, the number of data pages contained in all physical word lines in one first physical word line group is equal to or greater than N, that is, equal to or greater than the number of data pages contained in a N^{th} physical word line.

It can be understood that, proceeding to the next logical word line and physical word line refers to incrementing the serial number of the logical word line by one and correspondingly incrementing the serial number of the physical word line by n, where n is the number of the first physical word lines in the first physical word line group; for example, if the number of the first physical word lines in the first physical word line group is five, the serial number of the physical word line is incremented by five.
S904, identifying whether it is the second physical word line;
in some embodiments, identifying whether the current physical word line is a second physical word line, if yes, proceed to S905; if no, proceed to S906;
S905, combining several consecutive second physical word lines into a second physical word line group and mapping the second physical word line group to a logical word line and proceeding to the next logical word line and physical word line;
in some embodiments, if the current physical word line is the second physical word line, combining several consecutive second physical word lines into a second physical word line group, where all physical word lines in the second physical word line group are second physical word lines, and the number of data pages contained by all physical word lines in the second physical word line group is not less than the number of data pages contained by a N^{th} physical word line. For example, assuming that the first physical word line includes 1 data page, the second physical word line includes 2 data pages, and the third physical word line includes 3 data pages, . . . and the N^{th} physical word line includes N data pages, then consecutive N/2 or more than N/2 second physical word lines are combined into a second physical word line group, in this case, the number of data pages contained in all physical word lines in one second physical word line group is greater than N, that is, greater than or equal to the number of data pages contained in a N^{th} physical word line.

It can be understood that, proceeding to the next logical word line and physical word line refers to incrementing the serial number of the logical word line by one and correspondingly incrementing the serial number of the physical word line by n, where n is the number of the second physical word lines in the second physical word line group; for example, if the number of the second physical word lines in the second physical word line group is five, the serial number of the physical word line is incremented by five.
S906: identifying whether it is the (N−1)^{th} physical word line;
in some embodiments, after performing processing similar to the above for each physical word line, the identifying step reaches a penultimate physical word line, the penultimate physical word line is a physical word line in which the number of data pages is next only to that of the physical word line with the largest serial number.

If the current physical word line is the (N−1)^{th} physical word line, proceed to S907; and
if the current physical word line is not the (N−1)^{th} physical word line, proceed to S908.
S907, combining several consecutive (N−1)^{th} physical word lines into a second physical word line group and mapping the (N−1)^{th} physical word line group to a logical word line and proceeding to the next logical word line and physical word line;
in some embodiments, the number of data pages contained in all physical word lines in a (N−1)th physical word line group is greater than or equal to the number of data pages contained in a N^{th} physical word line.

It can be understood that the operation of proceeding to the next logical word line and physical word line is similar to the above-mentioned operation, which will not be repeated here.
S908, determining that the current physical word line is the N^{th} physical word line, where in this case, the current physical word line is directly mapped with a logical word line, and proceeds to the next logical word line and physical word line.
S909, identifying whether the current physical word line is the last physical word line of the physical block, that is, identifying whether all the physical word lines of the current physical block have been traversed, that is, identifying whether all the physical word lines of the current physical block have been mapped, if yes, proceeding to S910; if no, returning to S902.
S910, traversing all physical blocks of the flash memory device to complete the establishment of the mapping table.

In some embodiments, after traversing all the physical word lines of the current physical block, map the next physical block until all the blocks of the flash memory device are traversed to complete the establishment of the mapping table. It can be understood that the operation on each physical block is the same as the above-mentioned operation, which will not be repeated here.

In embodiment of the present application, by traversing all physical word lines in a physical block, one or more physical word lines are combined into a physical word line group, and a physical word line group is mapped with a logical word line, different types of NAND particles can be processed, which is beneficial to improving the compatibility of flash memory devices.
S504, writing to-be-written data into a physical word line corresponding to the physical word line group according to the physical word line group corresponding to the logical word line of each logic unit.

In some embodiments, after the corresponding physical word line group is determined according to the logical word lines, the to-be-written data is written to a physical word line corresponding to the physical word line group.

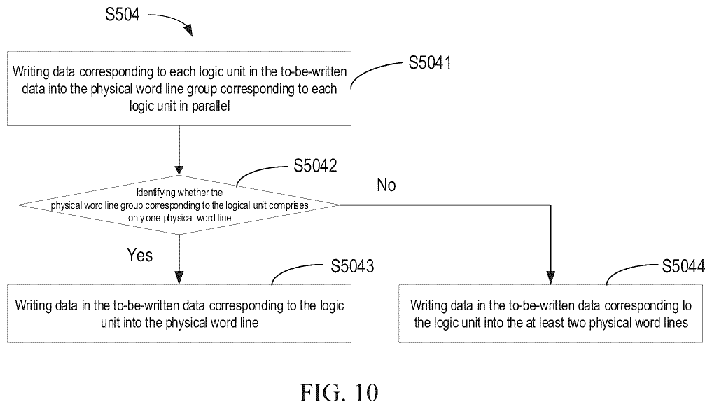

Referring further to FIG. 10, which is a detailed schematic flow chart of S504 in FIG. 5.

As shown in FIG. 10, S504 includes the following steps:
S5041: writing data corresponding to each logic unit in the to-be-written data into the physical word line group corresponding to each logic unit in parallel;
in some embodiments, the flash memory algorithm module delivers the to-be-written data according to the number of logic units and the number of data pages corresponding to one logic unit, where the data volume of the to-be-written data is equal to the number of logic units of a die of the flash memory device multiplied by the number of data pages corresponding to one logic unit multiplied by the size of one data page.

It can be understood that, if the to-be-written data corresponds to at least two logic units, write data corresponding to each logic unit in the to-be-written data into the physical word line group corresponding to each logic unit in parallel; and if the to-be-written data corresponds to one logic unit, the to-be-written data is directly written into the physical word line group corresponding to the logic unit.

In embodiments of the application, the number of data pages corresponding to one logic unit is equal to the maximum number of data pages of one physical word line of a block in the logic unit, for example: A block includes more than two types of physical word lines, in which the maximum number of data pages of a physical word line is N, and then the number of data pages corresponding to one logic unit is N, for example: A block includes three types of physical word lines, each type of physical word line includes one data page, two data pages and three data pages respectively, so the number of data pages corresponding to one logic unit is three.
S5042: identifying whether the physical word line group corresponding to the logical unit includes only one physical word line;
in some embodiments, identifying whether the physical word line group corresponding to the logical unit includes only one physical word line, and if so, proceed to S5043; otherwise, proceed to S5044.
S5043, writing data in the to-be-written data corresponding to the logic unit into the physical word line;
in some embodiments, the number of data pages corresponding to the logic unit in the to-be-written data is the number of data pages corresponding to the physical word line with the largest serial number; if only one physical word line is included in the physical word line group corresponding to the logic unit, then the number of data pages contained in the physical word line is equal to the number of data pages corresponding to the logic unit, and then the data corresponding to the logic unit in the to-be-written data can be directly written into the physical word line.
S5044, writing data in the to-be-written data corresponding to the logic unit into at least two physical word lines.
in some embodiments, since the physical word line group includes at least two physical word lines, the number of data pages contained in any one of the physical word lines in the physical word line group is less than the maximum number of data pages of a physical word line, that is, less than the number of data pages corresponding to the logic unit in the to-be-written data; in this case, it is necessary to write data in the to-be-written data corresponding to the logic unit into the at least two physical word lines.

In embodiments of the present application, the method further includes the following steps:
if the physical word line group corresponding to the logic unit includes one physical word line, writing data in the to-be-written data corresponding to the logic unit into the physical word line and determining that the writing is completed;
if the physical word line group corresponding to the logic unit includes at least two physical word lines, after writing data in the to-be-written data corresponding to the logic unit into the at least two physical word lines, filling invalid data (i.e., Dummy data) into a remaining space of the physical word line group and determining that the writing is completed;
where the data volume of the to-be-written data is equal to the number of logic units in one die of the flash memory device multiplied by the number of data pages corresponding to one logic unit multiplied by the size of one data page.

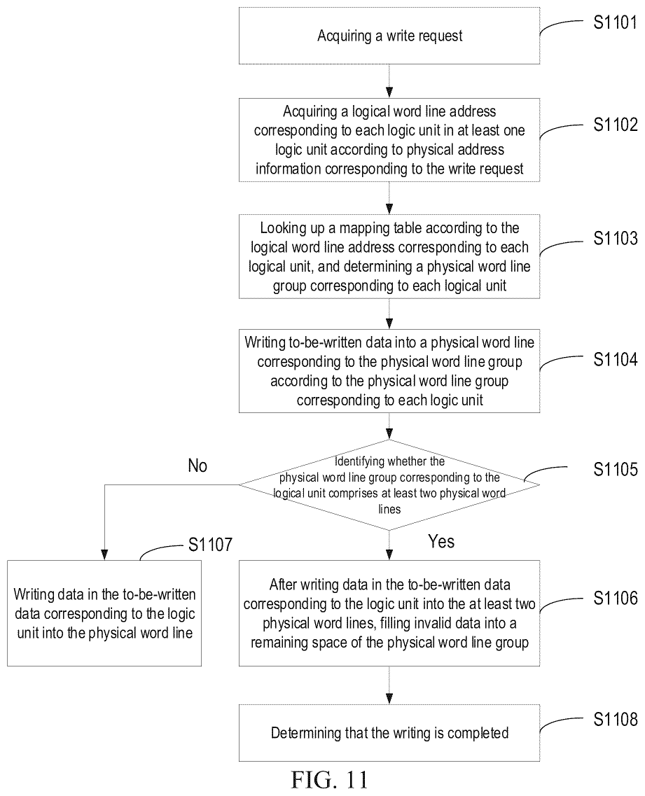

Referring further to FIG. 11, which is a schematic flow chart of writing data into a flash memory according to embodiments of the present application.

As shown in FIG. 11, the process of writing data into a flash memory includes the following steps:
S1101, acquiring a write request;
S1102: acquiring a logical word line address corresponding to each logic unit in at least one logic unit according to physical address information corresponding to the write request;
S1103, looking up a mapping table according to the logical word line address corresponding to each logical unit, and determining a physical word line group corresponding to each logical unit;
S1104, writing to-be-written data into a physical word line corresponding to the physical word line group according to the physical word line group corresponding to each logic unit;
S1105, identifying whether the physical word line group corresponding to the logical unit includes at least two physical word lines;
S1106, after writing data in the to-be-written data corresponding to the logic unit into the at least two physical word lines, filling invalid data into a remaining space of the physical word line group;
S1107, writing data in the to-be-written data corresponding to the logic unit into the physical word line; and
S1108, determining that the writing is completed.

In embodiments of the present application, a method for managing flash memory is provided and applied to a flash memory device, and the method includes the following steps: acquiring a write request, where the write request includes physical address information and to-be-written data; acquiring a logical word line address corresponding to each logic unit in at least one logic unit according to physical address information corresponding to the write request; looking up a mapping table according to the address of the logical word line corresponding to each logic unit, and determining a physical word line group corresponding to the logical word lines of each logic unit, where the mapping table includes a mapping relationship between the logical word lines and the physical word line group, the physical word line group includes at least one physical word line; and writing to-be-written data into a physical word line corresponding to the physical word line group according to the physical word line group corresponding to the logical word line of each logic unit.

On the one hand, by acquiring a logical word line address corresponding to each logic unit in at least one logic unit and looking up a mapping table according to the address of the logical word line corresponding to each logic unit, and determining a physical word line group corresponding to the logical word lines of each logic unit, in the present application, the mapping table can be used to map the logical word lines and the physical word line groups, the physical word line group includes at least one physical word line, and the numbers of data pages included in at least two physical word lines are not exactly the same, in the present application, different types of flash memory particles are adapted to improve compatibility of the flash memory device with flash memory particles.

On the other hand, by writing to-be-written data into a physical word line corresponding to the physical word line group according to the physical word line group corresponding to the logical word line of each logic unit, in the present application, the stability of data storage is improved.

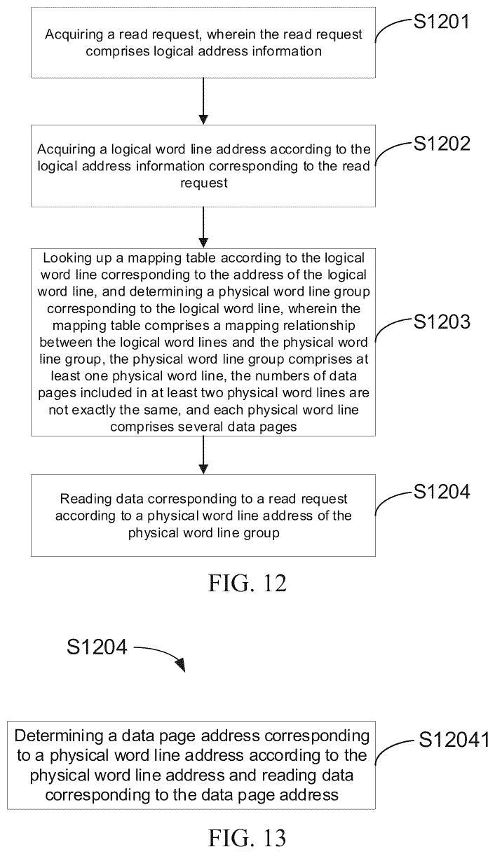

Referring further to FIG. 12, which is a schematic flow chart of another method for managing flash memory according to embodiments of the present application.

As shown in FIG. 12, the method for managing flash memory includes the following steps:
S1201, acquiring a read request, where the read request includes logical address information;
in some embodiments, the logical address information includes a logical word line address.
S1202, acquiring a logical word line address according to the logical address information corresponding to the read request;
in some embodiments, after receiving the read request sent by the flash algorithm module, the back-end module parses the read request and acquires logical address information corresponding to the read request, so as to acquire a logical word line address in the logical address information.
S1203, looking up a mapping table according to the logical word line corresponding to the address of the logical word line, and determining a physical word line group corresponding to the logical word line, where the mapping table includes a mapping relationship between the logical word lines and the physical word line group, the physical word line group includes at least one physical word line, the numbers of data pages included in at least two physical word lines are not exactly the same, and each physical word line includes a plurality of data pages.

It can be understood that each logical word line corresponds to one logical word line address, the mapping table stores a mapping relationship between the logical word lines and the physical word line groups, and according to the logical word line corresponding to the logical word line address, the physical word line group corresponding to the logical word line is determined; for instance, as shown in Table 1 above, the corresponding physical word line group can be determined by determining a serial number of the logical word line, and then at least one physical word line included in the physical word line group is determined, where each physical word line includes several data pages.
S1204, reading data corresponding to a read request according to a physical word line address of the physical word line group.

In some embodiments, each physical word line group corresponds to at least one physical word line, and the physical word line address of the physical word line group is the address of the first physical word line; since the physical word lines in the physical word line group are several continuous physical word lines, the data corresponding to the read request can be read according to the physical word line addresses of the physical word line groups.

Referring further to FIG. 13, which is a detailed schematic flow chart of S1204 in FIG. 12.

As shown in FIG. 13, S1204 includes the following steps:
S12041, determining a data page address corresponding to a physical word line address according to the physical word line address and reading data corresponding to the data page address.

It can be understood that the access address of NAND is: an address of the die (Die address)+an address of the logic unit (plane address)+an address of the physical block (Block address)+a physical word line address (WL address).

In some embodiments, the data page serves as a basic reading unit of the flash memory, and each data page has the same size. Therefore, according to the physical word line address, the data page address of each data page corresponding to the physical word line address can be determined, so that the data at the data page address corresponding to each data page can be read.

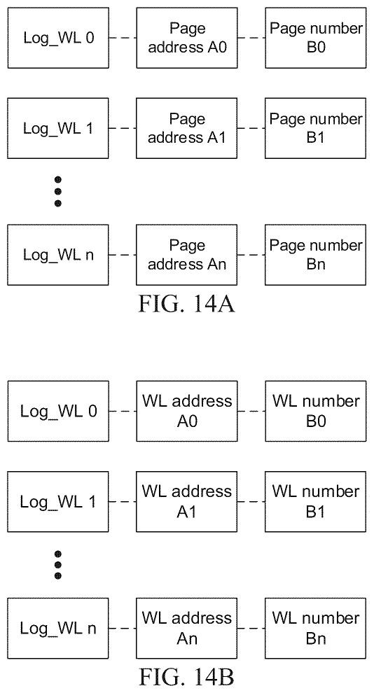

Referring to FIG. 14A, which is a schematic diagram of a mapping relationship between logical word lines and physical word lines according to embodiments of the present application.

As shown in FIG. 14A, a logical word line is mapped to an address of a data page and the number of data pages; for example, a logical word line 0 (Log_WL 0) is mapped to an address A0 (Page address A0) of a data page and the number of data pages (Page number B0).

Referring further to FIG. 14B, which is a schematic diagram of another mapping relationship between logical word lines and physical word lines according to embodiments of the present application.

As shown in FIG. 14B, a logical word line is mapped to an address of a physical word line and the number of physical word lines. For example, a logical word line 0 (Log_WL 0) is mapped to an address A0 (WL address A0) of a physical word line and the number of physical word lines (WL number B0).

It can be understood that a physical word line is composed of at least one data page, and an address of the physical word line may be converted into an address of the data page.

In embodiments of the present application, a logical word line address includes a number of logical data pages, where the size of each logical data page is equal to the size of one physical data page, and the starting address of a logical data page is the address of a first mapped physical word line.

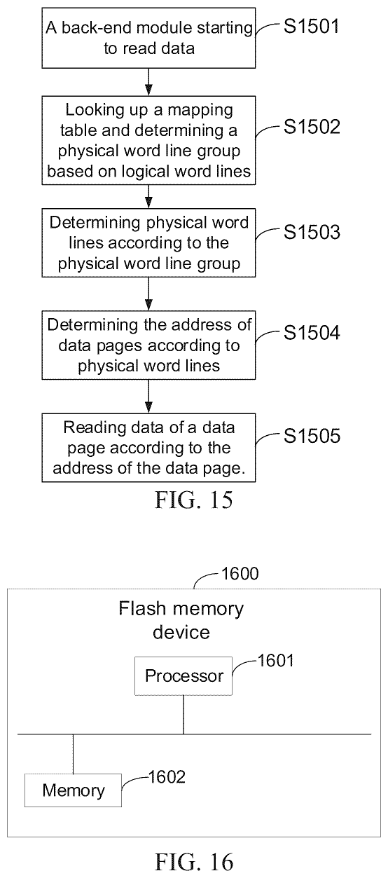

Referring further to FIG. 15, which is a schematic flow chart of reading data from a flash memory according to embodiments of the present application.

As shown in FIG. 15, the flow of reading data from a flash memory includes the following steps:
S1501, a back-end module starting to read data;
in some embodiments, the back-end module starts reading data in a flash memory after receiving a read request sent by a flash algorithm module.
S1502, looking up a mapping table and determining a physical word line group based on logical word lines;
in some embodiments, the back-end module determines the logical word lines according to the logical word line address in the logical address information corresponding to the read request, and looks up a mapping table to determine the physical word line group corresponding to the logical word lines.
S1503, determining physical word lines according to the physical word line group;
in some embodiments, the address of at least one physical word line in the physical word line group is determined according to the address of the physical word line group.
S1504, determining the address of data pages according to physical word lines;
in some embodiments, the address of at least one data page in the physical word line is determined according to the address of a physical word line.
S1505, reading data of a data page according to the address of the data page.

In some embodiments, the data in each data page is read according to the address of each data page.

Referring to FIG. 16, which is a schematic diagram illustrating the structure of a storage device according to embodiments of the present application.

As shown in FIG. 16, the storage device 1600 includes one or more processors 1601 and a memory 1602. In FIG. 16, processor 1601 is taken as an example.

The processor 1601 and the memory 1602 can be connected via a bus or other means, as shown in FIG. 16 via a bus connection.

The memory 1602, as a non-volatile computer-readable storage medium, can be used to store non-volatile software programs, non-volatile computer-executable programs, and modules. And the processor 1601 executes various functional applications and data processing of flash memory management methods by running non-volatile software programs, instructions, and modules stored in the memory 1602, that is, implementing the flash memory management method of the above-described method embodiments. The flash memory management method can be executed by various electronic devices with certain logical processing capabilities, such as control chips.

The memory 1602 may include high-speed random access memory, and may also include non-volatile memory, such as at least one disk storage device, flash memory device, or other non-volatile solid-state storage device. In some embodiments, the memory 1602 optionally includes memory remotely set relative to the processor 1601, which can be connected to the processor 1601 through a network. Examples of the above networks include but are not limited to the Internet, enterprise intranets, local area networks, mobile communication networks, and combinations thereof.

The modules storage in the memory 1602, when executed by one or more processors 1601, performs the flash memory management method of any of the above-described embodiments, e.g., performing the respective steps shown in FIG. 5 or FIG. 12 described above.

Example embodiments of the present application further provides a nonvolatile computer storage medium, the computer storage medium storing computer-executable instructions, the computer-executable instructions are executed by one or more processors, for example, the one or more processors may perform any of the above-described flash memory management method embodiments, for example, performing any of the above-described flash memory management method embodiments, for example, performing the various steps described above.

The apparatus embodiment described above is merely illustrative, where the units described as separate components may or may not be physically separated, and components displayed as units may or may not be physical units; i.e., they may be located in one position, or may be distributed on multiple network units. Some or all of the modules can be selected according to actual needs to achieve the purpose of the solutions of the embodiments.

From the descriptions of the above embodiments, those of ordinary skill in the art can clearly understand that various embodiments can be implemented through a software and general hardware platform or through hardware alone. Those of ordinary skill in the art can understand that all or part of the processes in the methods of the embodiments described above can be implemented by instructing relevant hardware through a computer program. The program can be stored in a computer-readable storage medium, and when executed, the program can include the processes of the embodiments of the methods as described above. The storage medium may be a magnetic disk, an optical disk, a read-only memory (ROM), or a random access memory (RAM), etc.

Finally, it should be noted that the above embodiments are only intended to illustrate the technical solutions of the present disclosure and are not intended to limit them.

Under the concept of the present disclosure, the technical features in the above embodiments or different embodiments can also be combined, steps can be implemented in any order, and there may exist many other variations in different aspects of the present disclosure as described above, which are not provided in detail for the sake of brevity. Despite the detailed description of the present disclosure with reference to the previous embodiments, those of ordinary skill in the art should understand that the technical solutions recorded in the various foregoing embodiments can still be modified or some of the technical features therein can be replaced with equivalent alternatives. Such modifications or replacements do not make the essence of the respective technical solutions depart from the scope of the technical solutions of various embodiments of the present disclosure.

1. A method for managing flash memory, applied to a flash memory device, comprising:
acquiring a write request, wherein the write request comprises physical address information and to-be-written data;
acquiring a logical word line address corresponding to each logic unit in at least one logic unit according to physical address information corresponding to the write request;
looking up a mapping table according to the logical word line address corresponding to each logic unit, and determining a physical word line group corresponding to the logical word lines of each logic unit, wherein the mapping table comprises a mapping relationship between the logical word lines and the physical word line group, the physical word line group comprises at least one physical word line, numbers of data pages comprised in at least two physical word lines are not exactly the same, and each physical word line comprises a plurality of data pages; and
writing to-be-written data into a physical word line corresponding to the physical word line group according to the physical word line group corresponding to the logical word line of each logic unit.

2. The method according to claim 1, wherein the numbers of data pages corresponding to the physical word line with a largest serial number in a physical word line group is equal to the number of data pages of one logical word line.

3. The method according to claim 1, wherein before acquiring a write request, the method further comprises:
establishing a mapping table, comprising:
if a physical block of the flash memory device comprises two types of physical word lines, namely a first physical word line and a second physical word line, then:
performing a mapping starting from the physical word line with the smallest serial number;
identifying whether a current physical word line is the first physical word line;
if yes, combining several consecutive first physical word lines into a first physical word line group and mapping the first physical word line group to a logical word line;
if no, determining that the current physical word line is a second physical word line, and mapping the current physical word line directly to one logical word line; and
traversing all physical word lines of a physical block,
wherein the first physical word line comprises a first number of data pages, the second physical word line comprises a second number of data pages, the second number is greater than the first number and the number of data pages of the logical word line is less than or equal to the number of data pages of the physical word line or the physical word line group corresponding to the logical word line, and the number of data pages of the logical word line is equal to the number of data pages corresponding to the physical word line with the largest serial number.

4. The method according to claim 3, wherein the establishing a mapping table further comprises:
if a physical block of the flash memory device comprises three types of physical word lines, namely a first physical word line, a second physical word line and a third physical word line, then:
performing a mapping starting from the physical word line with the smallest serial number;
identifying whether the current physical word line is the first physical word line, wherein the first physical word line comprises a first number of data pages;
if yes, combining several consecutive first physical word lines into a first physical word line group and mapping the first physical word line group to a logical word line;
if no, further identifying whether the current physical word line is a second physical word line, wherein the second physical word line comprises a second number of data pages, and the second number is greater than the first number;
if the current physical word line is the second physical word line, combining several consecutive second physical word lines into a second physical word line group and mapping the second physical word line group to a logical word line;
if the current physical word line is not the second physical word line, determining that the current physical word line is a third physical word line, and mapping the current physical word line directly to one logical word line; and
traversing all physical word lines of a physical block,
wherein the third physical word line comprises a third number of data pages, the third number is greater than the second number and the number of data pages of the logical word line is less than or equal to the number of data pages of the physical word line or the physical word line group corresponding to the logical word line, and the number of data pages of the logical word line is equal to the number of data pages corresponding to the physical word line with the largest serial number.

5. The method according to claim 4, wherein the establishing a mapping table further comprises:
if a physical block of the flash memory device comprises N types of physical word lines, namely a first physical word line, a second physical word line, . . . the (N−1)^{th} physical word line and an N^{th} physical word line, then:
if the current physical word line is not the second physical word line, continuing to identify whether the current physical word line is the third physical word line;
if yes, combining several third physical word lines into one third physical word line group and mapping the one third physical word line group to one logical word line;
repeating until it is identified whether the current physical word line is the (N−1)^{th} physical word line;
if the current physical word line is the (N−1)^{th} physical word line, combining several (N−1)^{th} physical word lines into one (N−1)^{th} physical word line group and mapping the one (N−1)^{th} physical word line group to one logical word line;
if the current physical word line is not the (N−1)^{th} physical word line, determining that the current physical word line is a (N−1)^{th} physical word line, and mapping the current physical word line directly to one logical word line; and
traversing all physical word lines of a physical block,
wherein N is a positive integer and greater than the third number, and the number of data pages of each logical word line is the same, and the number of data pages of the logical word line is less than or equal to the number of data pages of the physical word line or physical word line group corresponding to the logical word line, the logical word lines correspond one by one to the physical word lines with the maximum number of data pages, and the number of data pages of the logical word lines is equal to the number of data pages corresponding to the physical word line with the largest serial number.

6. The method according to claim 1, wherein the writing to-be-written data into a physical word line corresponding to the physical word line group according to the physical word line group corresponding to the logical word line of each logic unit comprises:
writing data corresponding to each logic unit in the to-be-written data into the physical word line group corresponding to each logic unit in parallel, wherein:
if the physical word line group corresponding to the logic unit comprises one physical word line, writing data in the to-be-written data corresponding to the logic unit into the physical word line; and
if the physical word line group corresponding to the logic unit comprises at least two physical word lines, writing data in the to-be-written data corresponding to the logic unit into the at least two physical word lines.

7. The method according to claim 6, further comprising:
if the physical word line group corresponding to the logic unit comprises one physical word line, writing data in the to-be-written data corresponding to the logic unit into the physical word line and determining that the writing is completed; and
if the physical word line group corresponding to the logic unit comprises at least two physical word lines, after writing data in the to-be-written data corresponding to the logic unit into the at least two physical word lines, filling invalid data into a remaining space of the physical word line group and determining that the writing is completed,
wherein a data volume of the to-be-written data is equal to the number of logic units in one die of the flash memory device multiplied by the numbers of data pages corresponding to one logic unit multiplied by a size of one data page.

8. The method according to claim 1, wherein
the physical address information comprises an address of a die, an address of at least one logic unit, an address of a physical block, and a logical word line address.

9. A method for managing flash memory, applied to a flash memory device, comprising:
acquiring a read request, wherein the read request comprises logical address information;
acquiring a logical word line address according to the logical address information corresponding to the read request;
looking up a mapping table according to the logical word line corresponding to the logical word line address, and determining a physical word line group corresponding to the logical word line, wherein the mapping table comprises a mapping relationship between the logical word lines and the physical word line group, the physical word line group comprises at least one physical word line, numbers of data pages comprised in at least two physical word lines are not exactly the same, and each physical word line comprises a plurality of data pages; and
reading data corresponding to a read request according to a physical word line address of the physical word line group.

10. The method according to claim 9, wherein the reading data corresponding to a read request according to a physical word line address of the physical word line group comprises:
determining a data page address corresponding to a physical word line address according to the physical word line address and reading data corresponding to the data page address.

11. The method according to claim 9, wherein the logical word line address comprises a plurality of logical data pages, wherein a size of each logical data page is equal to a size of one physical data page, and a starting address of a logical data page is the address of a first mapped physical word line.

12. A flash memory device, comprising a processor and a memory storing a program or an instruction that is capable of running on the processor, wherein the program or the instruction, when executed by the processor, causes the flash memory device to perform operations comprising:
acquiring a write request, wherein the write request comprises physical address information and to-be-written data;
acquiring a logical word line address corresponding to each logic unit in at least one logic unit according to physical address information corresponding to the write request;
looking up a mapping table according to the address of the logical word line corresponding to each logic unit, and determining a physical word line group corresponding to the logical word lines of each logic unit, wherein the mapping table comprises a mapping relationship between the logical word lines and the physical word line group, the physical word line group comprises at least one physical word line, numbers of data pages comprised in at least two physical word lines are not exactly the same, and each physical word line comprises a plurality of data pages; and
writing to-be-written data into a physical word line corresponding to the physical word line group according to the physical word line group corresponding to the logical word line of each logic unit.

13. The flash memory device according to claim 12, wherein the numbers of data pages corresponding to the physical word line with a largest serial number in a physical word line group is equal to the number of data pages of one logical word line.

14. The flash memory device according to claim 12, wherein before acquiring a write request, the method further comprises:
establishing a mapping table, comprising:
if a physical block of the flash memory device comprises two types of physical word lines, namely a first physical word line and a second physical word line, then:
performing a mapping starting from the physical word line with the smallest serial number;
identifying whether a current physical word line is the first physical word line;
if yes, combining several consecutive first physical word lines into a first physical word line group and mapping the first physical word line group to a logical word line;
if no, determining that the current physical word line is a second physical word line, and mapping the current physical word line directly to one logical word line; and
traversing all physical word lines of a physical block,
wherein the first physical word line comprises a first number of data pages, the second physical word line comprises a second number of data pages, the second number is greater than the first number and the number of data pages of the logical word line is less than or equal to the number of data pages of the physical word line or the physical word line group corresponding to the logical word line, and the number of data pages of the logical word line is equal to the number of data pages corresponding to the physical word line with the largest serial number.

15. The flash memory device according to claim 14, wherein the establishing a mapping table further comprises:
if a physical block of the flash memory device comprises three types of physical word lines, namely a first physical word line, a second physical word line and a third physical word line, then:
performing a mapping starting from the physical word line with the smallest serial number;
identifying whether the current physical word line is the first physical word line, wherein the first physical word line comprises a first number of data pages;
if yes, combining several consecutive first physical word lines into a first physical word line group and mapping the first physical word line group to a logical word line;
if no, further identifying whether the current physical word line is a second physical word line, wherein the second physical word line comprises a second number of data pages, and the second number is greater than the first number;
if the current physical word line is the second physical word line, combining several consecutive second physical word lines into a second physical word line group and mapping the second physical word line group to a logical word line;
if the current physical word line is not the second physical word line, determining that the current physical word line is a third physical word line, and mapping the current physical word line directly to one logical word line; and
traversing all physical word lines of a physical block,
wherein the third physical word line comprises a third number of data pages, the third number is greater than the second number and the number of data pages of the logical word line is less than or equal to the number of data pages of the physical word line or the physical word line group corresponding to the logical word line, and the number of data pages of the logical word line is equal to the number of data pages corresponding to the physical word line with the largest serial number.

16. The flash memory device according to claim 15, wherein the establishing a mapping table further comprises:
if a physical block of the flash memory device comprises N types of physical word lines, namely a first physical word line, a second physical word line, . . . the (N−1)^{th} physical word line and an N^{th} physical word line, then:
if the current physical word line is not the second physical word line, continuing to identify whether the current physical word line is the third physical word line;
if yes, combining several third physical word lines into one third physical word line group and mapping the one third physical word line group to one logical word line;
repeating until it is identified whether the current physical word line is the (N−1)^{th} physical word line;
if the current physical word line is the (N−1)^{th} physical word line, combining several (N−1)^{th} physical word lines into one (N−1)^{th} physical word line group and mapping the one (N−1)^{th} physical word line group to one logical word line;
if the current physical word line is not the (N−1)^{th} physical word line, determining that the current physical word line is a (N−1)^{th} physical word line, and mapping the current physical word line directly to one logical word line; and
traversing all physical word lines of a physical block,
wherein N is a positive integer and greater than the third number, and the number of data pages of each logical word line is the same, and the number of data pages of the logical word line is less than or equal to the number of data pages of the physical word line or physical word line group corresponding to the logical word line, the logical word lines correspond one by one to the physical word lines with the maximum number of data pages, and the number of data pages of the logical word lines is equal to the number of data pages corresponding to the physical word line with the largest serial number.

17. The flash memory device according to claim 12, wherein the writing to-be-written data into a physical word line corresponding to the physical word line group according to the physical word line group corresponding to the logical word line of each logic unit comprises:
writing data corresponding to each logic unit in the to-be-written data into the physical word line group corresponding to each logic unit in parallel, wherein:
if the physical word line group corresponding to the logic unit comprises one physical word line, writing data in the to-be-written data corresponding to the logic unit into the physical word line; and
if the physical word line group corresponding to the logic unit comprises at least two physical word lines, writing data in the to-be-written data corresponding to the logic unit into the at least two physical word lines.

18. The flash memory device according to claim 17, wherein the operations further comprise:
if the physical word line group corresponding to the logic unit comprises one physical word line, writing data in the to-be-written data corresponding to the logic unit into the physical word line and determining that the writing is completed; and
if the physical word line group corresponding to the logic unit comprises at least two physical word lines, after writing data in the to-be-written data corresponding to the logic unit into the at least two physical word lines, filling invalid data into a remaining space of the physical word line group and determining that the writing is completed,
wherein a data volume of the to-be-written data is equal to the number of logic units in one die of the flash memory device multiplied by the numbers of data pages corresponding to one logic unit multiplied by a size of one data page.

19. The flash memory device according to claim 12, wherein the physical address information comprises an address of a die, an address of at least one logic unit, an address of a physical block, and a logical word line address.
